(19) United States
(12) Patent Application Publication
(10) Pub. No.: US 2026/0305203 A1
(43) Pub. Date: Oct. 1, 2026

(54) ETCHING METHOD AND ETCHING APPARATUS

(71) Applicant: Hitachi High-Tech Corporation, Tokyo (JP)

(72) Inventors: Nobuya MIYOSHI, Hillsboro, OR (US); Nicholas McDowell, Hillsboro, OR (US); Phuc N. Phan, Hillsboro, OR (US)

(21) Appl. No.: 19/092,162

(22) Filed: Mar. 27, 2025

(51) Int. Cl. H01L 21/3213; H01J 37/32; H01L 21/67

(52) U.S. Cl. CPC H10P 50/267; H01J 37/32449; H10P 50/269; H10P 72/0421; H01J 2237/334

(57) ABSTRACT

A molybdenum film formed on a wafer placed on a wafer stage in a processing chamber inside a vacuum container is etched by carrying out: a step of supplying an oxygen radical or ozone and a hydrogen radical to the wafer to form an oxide layer on a surface of a metal molybdenum film; and a step of generating a plasma to form a reactive radical from a chlorine-containing gas and thereby eliminating/removing the oxide layer, and the step of forming the oxide layer and the step of eliminating/removing the oxide layer are repeatedly performed.

### BACKGROUND OF THE INVENTION

The present disclosure relates to an etching method and etching apparatus of a metal molybdenum (Mo) film.

In the field of semiconductor devices, both logic and memory devices are increasingly miniaturized further and becoming to have a three-dimensional device structure to satisfy a demand for reducing power consumption and increasing storage capacity. For example, in the logic device, since a Fin type FET (Fin Field-Effect transistor) is approaching the limit of miniaturization, device makers are developing Gate-All-Around (GAA) or Complementary FET (CFET) devices. In nonvolatile NAND devices, 3D-NAND flash memories have already become a mainstream, while in volatile DRAM devices, 3D-DRAM is being developed energetically.

Compared with devices having a two-dimensional structure, devices having a three-dimensional structure have a more complex steric structure and for their manufacture, isotropic etching capable of etching in a horizontal direction relative to a wafer plane is frequently used in addition to perpendicular (anisotropic) etching in which etching is performed in a perpendicular direction to the wafer plane.

Isotropic etching has conventionally been carried out by wet etching with a chemical liquid, but with the advance in miniaturization, problems such as pattern collapse due to the surface tension of the chemical liquid or an etching residue between minute spaces are becoming apparent. In isotropic etching, therefore, there is a growing tendency to replace the conventional wet etching using a chemical liquid with dry etching not using a chemical liquid.

As one example of dry etching of a metal molybdenum film, disclosed in US2022/0392752 is a processing method of carrying out surface modification with oxygen/chlorine plasma and then carrying out removal of the modified layer by exposure to argon ions thereby removing the molybdenum film.

As an isotropic dry etching method of a molybdenum film, disclosed in Journal of Vacuum Science and Technology A, 40 022602 (2022) is a method of modifying its surface with an oxygen plasma and then removing the modified layer by exposing it to a chlorine plasma and thereby removing the molybdenum film.

### SUMMARY OF THE INVENTION

For example, manufacturing steps of next-generation logic devices such as GAA and CFET and moreover, next-generation memory devices such as 3D-NAND and 3D-DRAM are expected to require a technology of etching a molybdenum film isotropically and at the same time, uniformly within a substrate plane and in a depth direction with atomic-layer level controllability.

FIG. 1 shows, as one example of it, isotropic processing of a molybdenum film 1 in a 3D-NAND device. Interlayer insulating films 2 have therebetween the molybdenum film 1 and immediately after formation of the film, molybdenum layers are electrically connected to each other in a slit 3. Since the molybdenum film 1 is required to be electrically separated by etching in a horizontal direction, isotropic etching of the molybdenum film 1 and in addition, highly precise and uniform control of an etching amount over the entire surface (within a substrate plane and in a depth direction) of a three-dimensional structure are required in this etching step.

Conventional wet etching has difficulty in highly precise control of an etching amount and moreover, pattern collapse due to the surface tension of a chemical liquid or an etching residue in a fine gap becomes a problem. Further, in voluntary etching with a reactive radical, due to a difference in etching rate of a molybdenum film between an upper part and a lower part of a pattern according to a supply rate of the radical, it is difficult to uniformly process the molybdenum film on a pattern having a three-dimensional structure.

The method disclosed in US2022/0392752 uses an argon ion for the removal of the modified molybdenum film and therefore it is expected to be difficult to achieve isotropic etching. Although Journal of Vacuum Science and Technology A, 40 022602 (2022) discloses a method of isotropic Atomic Layer Etching (ALE) of a molybdenum film, a method of controlling an etching rate has not been demonstrated. The method therefore has the problem that the processing rate cannot be adjusted/controlled freely.

The present disclosure is achieved with such problems of the conventional technology in consideration. An object is to provide an etching method and etching apparatus capable of controlling an etching rate in isotropic ALE of a molybdenum film.

An etching method according to one embodiment of the present disclosure is an etching method of etching a molybdenum film formed on a wafer, and the etching method includes: a first step of supplying an oxygen radical or ozone and a hydrogen radical to the wafer placed on a wafer stage in a processing chamber inside a vacuum container and thereby oxidizing a surface of the molybdenum film; and a second step of supplying the wafer with a chlorine radical which is a reactive radical by using a plasma to eliminate/remove an oxide layer formed on the surface of the molybdenum film. The first step and the second step are performed in repetition.

An etching apparatus according to another embodiment of the present disclosure includes: a vacuum container having therein a processing chamber and a plasma source provided above the processing chamber; a wafer stage which is provided in the processing chamber and on which a wafer having a molybdenum film formed thereon is placed; a first mass flow controller for supplying the plasma source with a processing gas to be used for plasma processing; and a control unit for controlling etching of the molybdenum film. The control unit carries out, in repetition: a first step of introducing, into the plasma source, an oxygen- and hydrogen-containing gas whose supply flow rate is adjusted by a first mass flow controller, causing the plasma source to generate a plasma, and thereby supplying the wafer with an oxygen radical or ozone, and a hydrogen radical thus generated to oxidize the surface of the molybdenum film; and a second step of introducing, into the plasma source, a chlorine-containing gas whose supply flow rate is adjusted by the first mass flow controller, causing the plasma source to generate a plasma, and thereby supplying the wafer with a chlorine radical thus generated to eliminate/remove an oxide layer formed on the surface of the molybdenum film.

In isotropic ALE of a molybdenum film, it becomes possible to continuously control an etching rate by using a hydrogen gas addition amount in the surface oxidizing step. Objects, configurations, and effects other than the above will be apparent from the description of the following embodiments.

### BRIEF DESCRIPTION OF THE DRAWINGS

FIG. 1 is a schematic view of an isotropic etching step of a molybdenum film in a process of manufacturing a device having a three-dimensional structure.

FIG. 2 is a schematic view of an etching procedure of the present embodiment.

FIG. 3 shows the experimental results of the relationship between an etching rate and a surface oxidation time in the etching method of the present embodiment.

FIG. 4 shows the experimental results of the relationship between an etching rate and an exposure time to a chlorine plasma in the etching method of the present embodiment.

FIG. 5 shows the experimental results of an influence of a gas, which is added in the surface oxidation step, on an etching rate in the etching method of the present embodiment.

FIG. 6 shows the experimental results of the dependence of an etching rate on an H₂/O₂ gas ratio in the etching method of the present embodiment.

FIG. 7 is a schematic view of an etching apparatus.

FIG. 8 shows the time sequence of the etching method of the present embodiment.

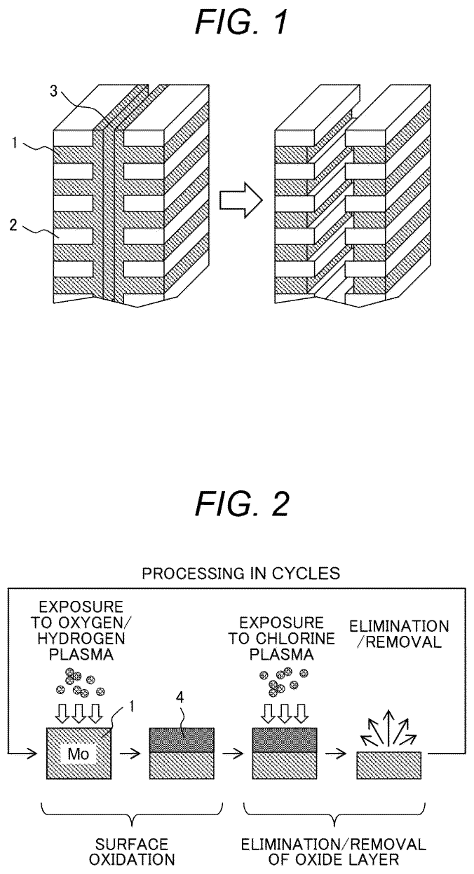

### DETAILED DESCRIPTION OF THE PREFERRED EMBODIMENTS

The embodiment of the present disclosure will hereinafter be described referring to drawings.

The etching procedure of the present embodiment is schematically shown in FIG. 2.

A first step includes introducing an oxygen- and hydrogen-containing gas into a vacuum container; using a plasma apparatus to generate a plasma inside the vacuum apparatus and thereby form an oxygen radical or ozone and a hydrogen radical; and forming an oxide layer 4 on the surface of a molybdenum film 1.

A second step includes evacuating the oxygen- and hydrogen-containing gas which has remained in a gas phase.

A third step includes introducing a chlorine-containing gas into the vacuum container; using the plasma apparatus to generate a plasma inside the vacuum apparatus and thereby form a chlorine radical; and eliminating/removing the oxide layer 4.

A fourth step includes evacuating both the chlorine-containing gas which has remained in the gas phase and the reaction product.

The first to fourth steps are repeated to control the etching amount to be a desired value in the end.

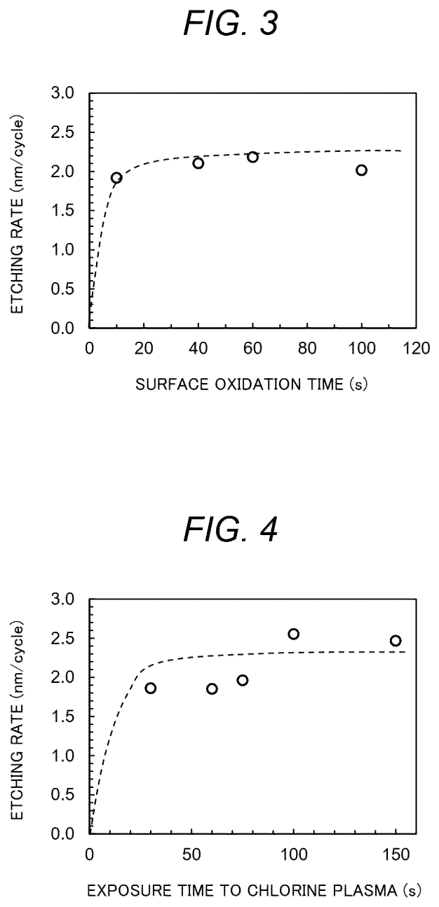

FIG. 3 shows the dependence of an etching rate (etching amount per cycle, nm/cycle) of the molybdenum film 1 on a surface oxidation time when the first to fourth steps are repeated. Here, the exposure time to a chlorine plasma in the third step is fixed to 60 seconds and the etching rate is measured at a varied surface oxidation time. It is apparent from FIG. 3 that an increase in the etching rate is saturated when the oxidation time is 10 seconds.

Next, FIG. 4 shows the dependence of the etching rate of the molybdenum film 1 on the exposure time to a chlorine plasma. Here, the surface oxidation time in the first step is fixed to 60 seconds and the etching rate is measured at a varied exposure time to a chlorine plasma. As in the surface oxidation shown in FIG. 3, it is apparent that an increase in the etching rate is saturated when the exposure time is 30 seconds.

The above results shown in FIG. 3 and FIG. 4 have proved that the etching process of the present embodiment has a self-limiting property in both the first step (surface oxidation) and the third step (elimination/removal) and is therefore an ALE process. In isotropic dry etching of the molybdenum film 1, using the present etching process enables highly accurate control of an etching amount and uniform processing within a wafer plane and in a depth direction.

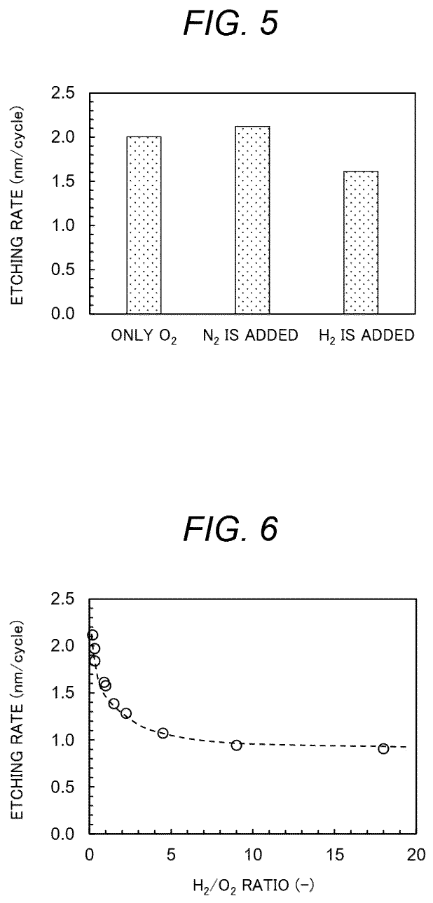

Next, an etching rate when the first step is performed by adding a nitrogen (N₂) gas or a hydrogen gas (H₂) to an oxygen (O₂) gas is shown in FIG. 5. An etching rate when only an oxygen gas is used (the term “only O₂” is used in FIG. 5) and that when a nitrogen gas is added to an oxygen gas (the term “N₂ is added” is used in FIG. 5) are approximately 2 nm/cycle and therefore no large difference is found. On the other hand, an etching rate when a hydrogen gas is added to an oxygen gas (the term “H₂ is added” is used in FIG. 5) is 1.6 nm/cycle and therefore, a reduction of approximately 20% is found.

Next, the dependence of an etching rate on an H₂/O₂ ratio when an oxygen gas is partially substituted with a hydrogen gas is therefore shown in FIG. 6. It is apparent that an etching rate is approximately 2 nm/cycle when the ratio is 0, that is, when only an O₂ gas is used; with an increase in the addition amount of a hydrogen gas, the H₂/O₂ ratio increases and an etching rate shows a monotonous decrease; and the etching rate can be reduced even to 1 nm/cycle. The above results shown in FIG. 6 have proved that addition of a hydrogen gas in the first step (surface oxidation) enables continuous control of the etching rate within a range of 1 to 2 nm/cycle.

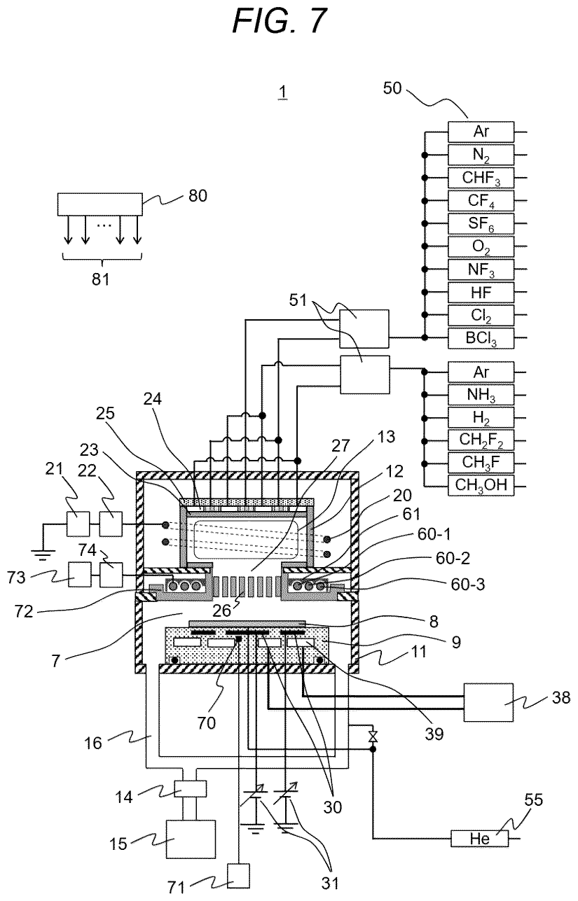

Referring to FIG. 7, the overall constitution of a plasma etching apparatus (also called “plasma processing apparatus”) 1 will next be described. A processing chamber 7 of the plasma etching apparatus 1 is constituted of a base chamber (vacuum container) 11 and it has a wafer stage 9 therein to place a wafer 8 thereon. The processing chamber 7 has, in the upper portion thereof, a plasma source (ICP plasma source) using an ICP (Inductively Coupled Plasma) discharge system. The ICP plasma source is used for cleaning of the inner wall of the chamber 11 by a plasma or formation of a reactive radical by the plasma.

The processing chamber 7 has, in the upper portion thereof, a cylindrical type discharge tube 12 that constitutes the ICP plasma source, and the discharge tube 12 has an ICP coil 20 on the outside thereof. A high-frequency power source 21 for plasma formation is connected to the ICP coil 20 via a matching device 22. As the frequency of high frequency power of the high-frequency power source 21, a frequency band of several tens of MHz such as 13.56 MHz is used. The discharge tube 12 has thereabove a top plate 25. The top plate 25 has therebelow a gas dispersion plate 24 and a shower plate 23, and a processing gas is introduced into the discharge tube 12 via the gas dispersion plate 24 and the shower plate 23. The discharge tube 12 and the high-frequency power source 21 constitute the plasma source.

The supply flow rate of the processing gas is adjusted by mass flow controllers 50 installed respectively for gas types. The mass flow controllers 50 have, on the downstream thereof, gas distributors 51, which supply a gas to be supplied to the vicinity of the center of the discharge pipe 12 and a gas to be supplied to the vicinity of the periphery thereof while controlling the flow rate or composition of these gases independently. The space distribution of the partial pressure of the processing gases can therefore be controlled in detail. FIG. 7 shows a representative using example of processing gases such as argon (Ar), N₂, fluoroform (CHF₃), carbon tetrafluoride (CF₄), sulfur hexafluoride (SF₆), O₂, nitrogen trifluoride (NF₃), hydrogen fluoride (HF), chlorine (Cl₂), boron trichloride (BCl₃), ammonia (NH₃), H₂, difluoromethane (CH₂F₂), fluoromethane (CH₃F), and methanol (CH₃OH), but another gas may be used.

Below the processing chamber 7, an exhaust mechanism 15 is connected thereto via a vacuum exhaust pipe 16 to reduce the pressure of the processing chamber 7. The exhaust mechanism 15 is comprised of, for example, but not limited to, a turbo molecular pump, a mechanical booster pump, or a dry pump. To adjust the pressure of the processing chamber 7, a pressure adjusting mechanism 14 is placed for the vacuum exhaust pipe 16 which is connected to the exhaust mechanism 15.

The wafer stage 9 has thereabove an IR lamp unit for heating the wafer 8. The IR lamp unit has an IR lamp 60, a reflection plate 61 for reflecting IR light, and an IR light transmission window 72. This apparatus uses, as the IR lamp 60, circle type (circular) IR lamps 60-1, 60-2, and 60-3.

The IR lamp 60 emits light (here, it is called “IR light”) mainly comprised of light in the visible to infrared light region. In the above example, three circles of the IR lamp 60-1, 60-2, and 60-3 are placed concentrically, but two circles or four or more circles may be placed. The IR lamp 60 has thereabove the reflection plate 61 for reflecting the IR light in a downward direction (toward the position of the wafer).

The IR lamp 60 has an IR lamp power source 73 connected thereto and they have therebetween a high-frequency cut filter 74 for preventing the noise of high frequency power from flowing in the IR lamp power source 73. The IR lamp power source 73 has a function of independently controlling the power to be supplied to the IR lamps 60-1 to 60-3 and therefore can adjust the diameter-direction distribution of the heating amount of the wafer 8 (the wiring is partially omitted from FIG. 7 to avoid it from complicating the drawing).

The IR lamp unit has, at the center thereof, a flow channel 27. This flow channel 27 has a slit plate 26 with a plurality of holes opened therethrough for blocking ions or electrons generated in the plasma and transmitting only a neutral gas or a neutral radical to expose the wafer 8 thereto.

The wafer stage 9 has therein a flow channel 39 of a refrigerant for cooling the stage therewith and the refrigerant is circulated and supplied through the flow channel 39 by a chiller 38. The stage has a plate-like electrode plate 30 buried therein to fix the wafer 8 by electrostatic adsorption, and a DC power source 31 is connected to it.

To enable efficient cooling of the wafer 8, a helium (He) gas whose flow rate is adjusted by a mass flow controller 55 is supplied between the back surface of the wafer 8 and the wafer stage 9. The surface of the wafer stage 9 (the surface on which the wafer 8 is placed) is coated with a resin such as polyimide in order to prevent the back surface of the wafer 8 from being scratched by heating or cooling the wafer while causing it to adsorb to the stage. Further, the wafer stage 9 has therein a thermocouple 70 for measuring the temperature of the stage and this thermocouple 70 is connected to a thermocouple thermometer 71.

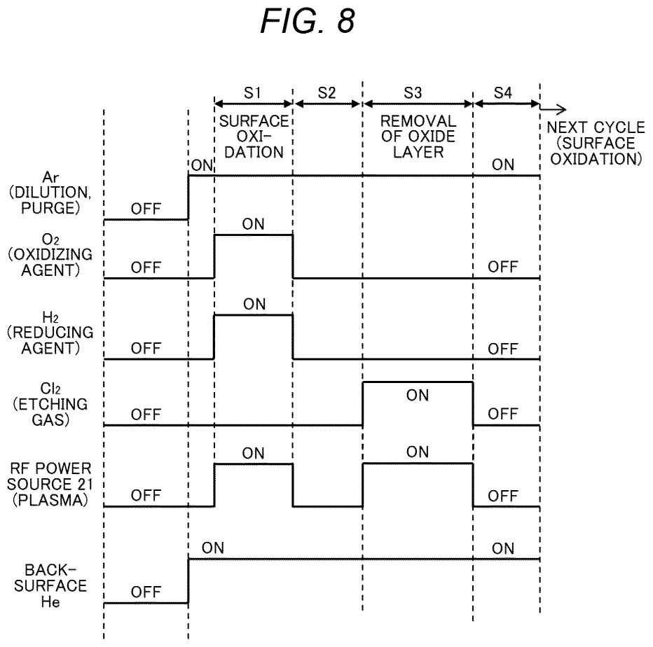

The etching process of the present embodiment will next be described referring to FIG. 8. The sequence of FIG. 8 is controlled by a control unit 80 of the etching apparatus 1. The control unit 80 is connected to the power sources (21, 73, and 31), the mechanisms (15 and 14), and the controllers (50 and 55) via a control line 81 and controls them to perform a predetermined sequence.

First, after the wafer 8 is transferred to the processing chamber 7 via a transfer port (not shown) provided in the processing chamber 7, power is supplied to the DC power source 31 to fix the wafer 8 to the wafer stage 9 by electrostatic adsorption and at the same time, a He gas for wafer cooling is supplied to the back surface of the wafer 8. The pressure of the He gas is, for example, 1 kPa or 2 kPa.

Next, an Ar gas for diluting an etching gas is supplied to the processing chamber 7 via the mass flow controller 50, the gas distributor 51, and the shower plate 23. The flow rate of the Ar gas is, for example, 0.5 L, 1 L, or 2 L. After that, supply of the Ar gas for dilution is continued until the completion of the etching.

In the first step S1, an oxygen- and hydrogen-containing gas is introduced into the processing chamber 7; the high-frequency power source (RF power source: Radio Frequency power source) 21 is turned ON to form a plasma in a discharge region 13; and an oxygen radical or ozone, and a hydrogen radical are formed. The gas flow rate when the oxygen gas is used is, for example, 0.1 L, 0.5 L, 1 L, or 2 L, while the gas flow rate when the hydrogen gas is used is, for example, 0.1 L, 0.5 L, 1 L, or 2 L. The power to be supplied to the high-frequency power source 21 is, for example, 1000 W, 1500 W, or 2000 W. The total pressure of the diluting Ar gas and the oxygen gas is, for example, 50 Pa, 100 Pa, 200 Pa, or 300 Pa. The temperature of a substrate (wafer) during radical processing is, for example, in a range of from −10° C. to +100° C. These reaction species formed in the plasma are supplied to the processing chamber 7 via the flow channel 27 and the slit plate 26 and adsorb to the surface of the wafer 8. These reaction species react with the surface of the molybdenum film 1 to form an oxide layer 4 containing molybdenum and an oxygen atom on the surface of the molybdenum film 1. The oxygen radical and ozone act to proceed the surface oxidation and on the contrary, the hydrogen radical acts to suppress the oxidation reaction by a reduction effect to control the film thickness of the oxide film. Then, the high-frequency power source 21 is turned OFF to stop plasma generation and thereby stop supply of the reaction species.

In the second step S2, an oxygen- and hydrogen-containing gas, which has remained in the gas phase, is evacuated to prepare for gas supply in the subsequent third step S3.

In the third step S3, a chlorine-containing gas is introduced into the processing chamber 7; the high-frequency power source 21 is turned ON to form a plasma in the discharge region 13; and a chlorine radical is formed. When the chlorine gas is used, its flow rate is, for example, 0.05 L, 0.1 L, 0.2 L, 0.3 L, 0.5 L, or 1 L. The total pressure of the dilution gas and the etching gas is, for example, 50 Pa, 100 Pa, 200 Pa, or 300 Pa. The temperature of a substrate (wafer) during radical processing is, for example, in a range of from −10° C. to +100° C. The chlorine radical generated in the plasma is supplied to the processing chamber 7 via the flow channel 27 and the slit plate 26 and it adsorbs to the surface of the oxide layer 4. Due to the reaction between the chlorine radical and the oxide layer 4, the oxide layer changes into a volatile reaction product containing molybdenum, oxygen, and chlorine. Then, the high-frequency power source 21 is turned OFF to stop the plasma generation and thereby stop the supply of the reactive radical.

In the fourth step S4, the reaction product and chlorine-containing gas that have remained in the gas phase are evacuated to prepare for a subsequent cycle (first step S1).

By repeating the steps from the first step S1 to the fourth step S4 plural times, the etching amount of the molybdenum film is controlled into a desired value in the end. In addition, by controlling the flow rate of the hydrogen-containing gas to be added in the first step S1, the etching amount (etching rate, nm/cycle) of one cycle is controlled.

As described in FIGS. 3 and 4, the etching rate in the etching of the present embodiment is saturated relative to the surface oxidation time and exposure time to chlorine plasma and this enables uniform etching within the wafer plane and in the depth direction.

As shown in FIG. 6, a hydrogen-containing gas is added in the first step S1 (surface oxidation) to control the oxidation and reduction balance of the surface, making it possible to control the thickness of the oxide film and control the etching rate into a desired value.

In the present embodiment, an example of controlling the wafer temperature during exposure of radicals by a wafer stage temperature is shown but a wafer temperature control method is not limited to it. For example, the IR lamp 60 may be used for heating the wafer and controlling the temperature.

It should be noted that the present disclosure is not limited to the embodiments described above, and includes various modification. For example, the embodiments described above have been described in detail to simply describe the present disclosure, and are not necessarily required to include all the described configurations. In addition, part of the configuration of one embodiment can be replaced with the configurations of other embodiments, and in addition, the configuration of the one embodiment can also be added with the configurations of other embodiments. In addition, part of the configuration of each of the embodiments can be subjected to addition, deletion, and replacement with respect to other configurations.

What is claimed is:

1. An etching method of etching a metal molybdenum film formed on a wafer, comprising:
a first step of supplying an oxygen radical or ozone and a hydrogen radical to the wafer placed on a wafer stage in a processing chamber inside a vacuum container and thereby oxidizing a surface of the molybdenum film; and
a second step of supplying the wafer with a reactive radical by using a plasma to eliminate/remove an oxide layer on the surface of the molybdenum film, wherein
the first step and the second step are performed in repetition.

2. The etching method according to claim 1, wherein
a modified layer is formed on the surface of the molybdenum film while supplying a helium gas between the wafer and the wafer stage.

3. The etching method according to claim 1, wherein
in the first step, the surface of the molybdenum film is oxidized by introducing an O₂-containing gas inside the vacuum container to generate the plasma in the vacuum container.

4. The etching method according to claim 1, wherein
in the first step, the surface of the molybdenum film is oxidized by introducing a H₂-containing gas into the vacuum container to generate the plasma in the vacuum container.

5. The etching method according to claim 1, wherein
in the second step, the oxide layer formed on the surface of the molybdenum film in the first step is eliminated/removed by introducing a Cl₂-containing gas inside the vacuum container to generate the plasma in the vacuum container.

6. An etching apparatus, comprising:
a vacuum container having therein a processing chamber and a plasma source provided above the processing chamber;
a wafer stage which is provided in the processing chamber and on which a wafer having a molybdenum film formed thereon is placed;
a first mass flow controller for supplying the plasma source with a processing gas; and
a control unit for controlling the etching of the molybdenum film, wherein
the control unit carries out, in repetition: a first step of introducing, into the plasma source, an oxygen- and hydrogen-containing gas whose supply flow rate is adjusted by the first mass flow controller, causing the plasma source to generate a plasma, and thereby supplying the wafer with an oxygen radical or ozone, and a hydrogen radical to oxidize a surface of the molybdenum film; and a second step of introducing, into the plasma source, a chlorine-containing gas whose supply flow rate is adjusted by the first mass flow controller, causing the plasma source to generate a plasma, and thereby supplying the wafer with a reactive radical thus generated to eliminate/remove an oxide layer formed on the surface of the molybdenum film.

7. The etching apparatus according to claim 6, further comprising
a second mass flow controller for supplying a helium gas between the wafer and the wafer stage, wherein
in the first step of forming the oxide layer on the surface of the molybdenum film, the control unit introduces the helium gas whose supply flow rate is adjusted by the second mass flow controller between the wafer and the wafer stage.
